(19) United States
(12) Patent Application Publication
(10) Pub. No.: US 2025/0105227 A1
(43) Pub. Date: Mar. 27, 2025

(54) ELECTRONIC CIRCUIT

(71) Applicant: STMicroelectronics International N.V., Geneva (CH)

(72) Inventor: Jonathan GODILLON, Ramonville-Saint-Agne (FR)

(73) Assignee: STMicroelectronics International N.V., Geneva (CH)

(21) Appl. No.: 18/890,617

(22) Filed: Sep. 19, 2024

(30) Foreign Application Priority Data
Sep. 26, 2023 (FR) 2310184

(51) Int. Cl. H01L 25/16; H01L 23/00; H01L 23/64

(52) U.S. Cl. CPC H01L 25/16; H01L 23/647; H01L 24/32; H01L 2224/32145; H01L 2924/13064; H01L 2924/13091

(57) ABSTRACT

An electronic circuit includes a first die, having a GaN transistor, and a second die, stacked so that an element of the second die electrically connects a first node and a second nodes of the first die respectively coupled to a conduction node and to a control node of the GaN transistor.

### CROSS-REFERENCE TO RELATED APPLICATION(S)

This application claims the priority benefit of French patent application number 2310184, filed on Sep. 26, 2023, entitled “Circuit électronique,” which is hereby incorporated by reference to the maximum extent allowable by law.

### BACKGROUND

### Technical Field

The present disclosure generally concerns electronic circuits and the associated methods.

### Description of the Related Art

On manufacturing of an electronic circuit, it can be useful to test certain components of the circuit before the circuit is fully completed or assembled with other circuits.

### BRIEF SUMMARY

It would be beneficial to provide electronic circuits having components that can be tested during the manufacturing and this, while reducing manufacturing and design costs.

Embodiments of the present disclosure overcome all or part of the disadvantages of known circuits.

An embodiment provides an electronic circuit including a first die, having a GaN transistor, and a second die, stacked so that an element of the second die electrically connects a first node and a second nodes of the first die respectively coupled to a conduction node and to a control node of the GaN transistor.

An embodiment provides a method of manufacturing an electronic circuit including:
stacking a first die, having a GaN transistor and a second die, so that an element of the second die electrically connects a first node and a second node of the first die respectively coupled to a conduction node and to a control node of the GaN transistor.

Circuit according to claim 1 or method according to claim 2, wherein said element of the second die including a conductive track arranged on a first surface of the second die.

According to an embodiment, the second die is a die based on silicon.

According to an embodiment, the second die including at least one transistor.

According to an embodiment, the transistor of the second die is of MOS type and the GaN transistor of the first die is of HEMT type.

According to an embodiment, said transistor of the second die has:
a first conduction node connected to the first node of the first die via said element; and
a second conduction node connected to the control node of the transistor of the first die via another element.

According to an embodiment, an electric contact between said element of the second die and the first and second nodes of the first die is a weld or a solder.

According to an embodiment, the second node of the first die is coupled to the control node of the GaN transistor via an electronic component.

According to an embodiment, said electronic component is active or passive.

According to an embodiment, said electronic component is configured to allow the establishing of an automatic operating point of the GaN transistor.

According to an embodiment, said electronic component is a resistor.

According to an embodiment, before the stacking of the first and of the second dies, the first and second nodes of the first die are disconnected from each other.

According to an embodiment, before the stacking of the first and of the second dies, a test of the electronic component is performed.

In one embodiment, an electronic circuit includes a first die. The first die includes a GaN transistor having a control node and a conduction node. The first die includes a first node coupled to the conduction node and a second node coupled to the control node. The electronic circuit includes a second die stacked with the first die and including an element electrically coupling the first node to the conduction node, and electrically coupling the second node to the control node.

In one embodiment, a method of manufacturing an electronic circuit includes stacking a first die and a second die. The stacking includes electrically coupling, with an element of the second die, a first node of the first die to a conduction node of a GaN transistor of the first die and electrically coupling, with the element, a second node of the first die to a control node of the GaN transistor.

In one embodiment, a device includes a first die. The first die includes a first GaN transistor including a control node and a conduction node, a first surface, a first conductive track coupled to the conduction node and exposed at the first surface, and a second conductive track coupled to the control node and exposed at the first surface. The device includes a second die. The second die includes a second surface mounted to the first surface of the first die and a third conductive track exposed at the second surface and electrically coupled to the first conductive track and the second conductive track.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically illustrates a portion of an electronic circuit according to an embodiment;

FIG. 2 illustrates a top view of the electronic circuit portion of the embodiment of FIG. 1;

FIG. 3 schematically illustrates a top view of an embodiment of an electronic circuit;

FIG. 4 schematically illustrates a cross-section view A-A of a portion of the electronic circuit of the embodiment of FIG. 3;

FIG. 5 schematically illustrates the electronic circuit of FIG. 3 according to an embodiment; and

FIG. 6 illustrates a method of manufacturing the electronic circuit of FIG. 3.

### DESCRIPTION OF EMBODIMENTS

Like features have been designated by like references in the various figures. In particular, the structural and/or functional features that are common among the various embodiments can have the same references and can dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

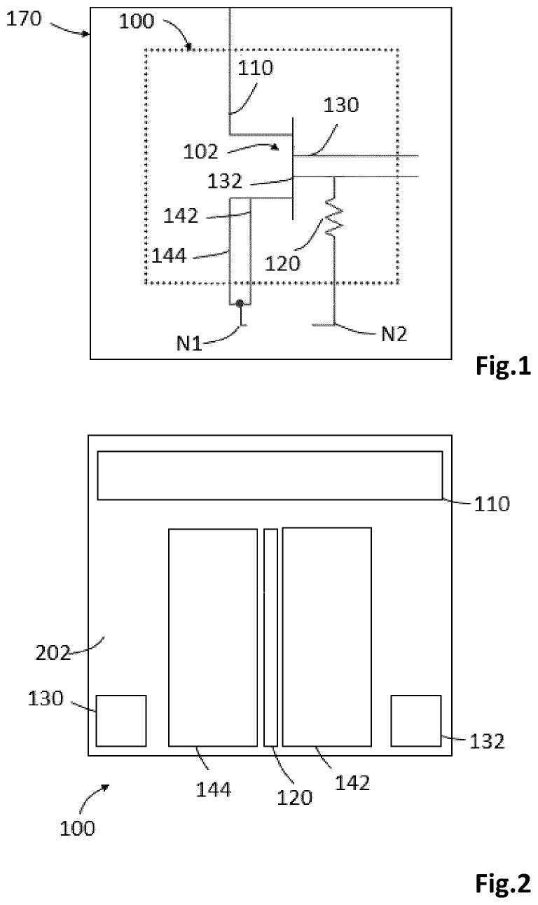

FIG. 1 schematically illustrates an electronic circuit 170 according to an embodiment.

More particularly, FIG. 1 shows a first circuit of the electronic circuit 170 formed in a first die 100 which including a GaN transistor 102. A first node N1 of the first die 100 is coupled to a conduction node 142, 144, for example the source, of GaN transistor 102. A second node N2 of first die 100 is coupled to a control node 130,132, for example the gate, of GaN transistor 102. Transistor 102 also including another conduction node 110, for example, the drain.

In the shown example, conduction node 142, 144 and controlling node 130, 132 include two tracks each, it is however possible to envisage a single track for each of them.

In an example, the GaN transistor is of high electron mobility type (HEMT).

By the terms “GaN transistor”, there is meant that the substrate of the transistor is an alloy based on gallium nitride with however the possibility for other elements to be incorporated in this basic alloy. This particularly encompasses transistors including one or a plurality of heterojunctions formed by alloys such as AlGaN/InGaN, AlInAs/GaInAs, GaInAs/AlGaAs, AlGaAs/AlGa.

In the shown example, the second node N2 of first die 100 is coupled to the control node 132 of the GaN transistor via an electronic component 120. In an example, electronic component 120 is configured to allow the establishing of an automatic operating point of the GaN transistor. In another example, electronic component 120 is an active or passive component. Electronic component 120 is for example a resistor.

In the shown example, nodes N1 and N2 are disconnected, in other words are not directly connected. This enables to perform test measurements, for example to determine a physical parameter of component 120, for example its resistance and/or a leakage current of the gate 132 of transistor 102.

FIG. 2 illustrates a top view of a portion of the electronic circuit 170 of the embodiment of FIG. 1. More particularly, FIG. 2 shows first die 100. In the shown example, a connection pad of the conduction node 110 of GaN transistor 102, for example the drain, is arranged on a high portion of die 110 in the form for example of a rectangle arranged inside and/or on top of a substrate 202 for example made of GaN. Connection pads coupled to tracks 130, 132 forming the control node are arranged in a corner opposite to conduction node 110 on the same surface of substrate 202. Connection pads coupled to tracks 142, 144 forming the source of transistor 102 are arranged for example inside and/or on top of the same surface of substrate 202 and this, between the pads coupled to tracks 130 and 132. Between the connection pads coupled to tracks 142, 144 is located electronic component 120, which in this example, is a resistor arranged on the same surface of substrate 202. Electronic component 120 is electrically insulated, on first die 100, from the connection pads coupled to tracks 142, 144. In a way not illustrated, electronic component 120 is for example coupled to tracks 130 and 132 by vias and/or or conductive tracks in substrate 202.

The examples of FIGS. 1 and 2 enable to measure, for example, one or a plurality of the physical parameters of electronic component 120. However, once the measurement or the test have been performed, to form a complete circuit, nodes N1 and N2 for example have to be electrically connected. Such is for example the case when a cascode structure is desired to be implemented from first die 100.

It is possible to form this connection by performing a wire bonding between nodes N1 and N2. This is however expensive and this can induce reliability issues as well as introduce parasites on the signals.

The described embodiments provide, as a complement to first die 100, a second die, stacked with the first die so that an element of the second die electrically connects the first node N1 and the second node N2 of the first die. This enables to perform measurements on the first die, for example on electronic component 120, and once the assembly has been formed with the second die, to obtain a complete circuit, for example a circuit of cascode type. Another advantage is that, conversely to the use of a wire bonding, the occurrence of parasitic elements of “RLC” type is limited. This further induces a better stability during signal transitions and limits the costs linked to welds and to the additional material.

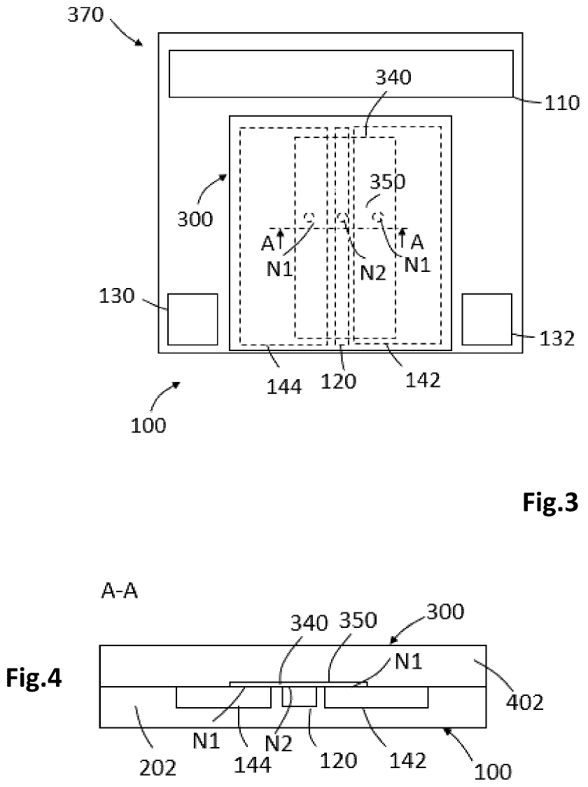

FIG. 3 schematically illustrates a top view of an embodiment of an electronic circuit 370.

Circuit 370 including first die 100, similar to that described in FIGS. 1 and 2, as well as a second die 300. The first and the second dies 100, 300 are stacked. In an example, second die 300 is a die based on silicon or on a semiconductor. In another example, second die 300 including at least one circuit with a transistor.

In the shown example, second die 300 is stacked above the first die. Second die 300 including an element 350 arranged on a surface of second die 300 which faces the surface located at the front of first die 100. The element 350 of the second die including for example a conductive track, for example, metallic or made of a heavily-doped semiconductor. This conductive track is for example formed by or connected to a drain 340 or a source or a gate of a transistor of second die 300.

In the example of FIG. 3, it can be seen by transparency that the second die covers the connection pads coupled to tracks 142, 144 as well as electronic component 120.

In the shown example, element 350 partly covers the connection pads coupled to tracks 142, 144. In another example, element 350 entirely covers these pads. As shown in FIG. 1, in one embodiment the source of transistor 102 is divided into two portions 142, 144 both connected to node N1. Element 350 electrically connects the first node NI and the second node N2 of first die 100, in other words element 350 electrically connects the source of transistor 102 to second node N2, which is itself connected to electronic component 120. In an example where the source of transistor 102 is formed of a single conductive track, element 350 electrically connects this track, and thus the source of transistor 102, to second node N2.

In an example, an electric contact between the element of second die 300 and the first and second nodes N1, N2 of first die is formed with a welding or a soldering. In another example, this electric contact is formed via a die attach adhesive film for example containing silver and/or nickel, and/or copper and/or gold and/or palladium. A thermal treatment accompanied or not by the application of a pressure is also used to form the contact, in one embodiment.

The example of FIG. 3 enables to increase the contact surface area between the first and the second die to form the contact between nodes N1 and N2, conversely to a wire connection having its contact surface areas decreased and fragile.

FIG. 4 schematically illustrates an A-A cross-section view of a portion of the electronic circuit of the embodiment of FIG. 3. The A-A cross-section cuts the first and the second die 100, 300 at the level of the connection pads of source 142, 144, as well as electronic component 120 and element 350.

In the shown example, the pads of source 142, 144 are arranged in substrate 202 from the surface of first die 100 which faces second die 300. Element 350 is arranged in a substrate 402 of second die 300 from the surface of the second die facing the first die. Element 350 partly covers the pads of the source 142, 144 of the transistor 102 of the first die 100 at the level of node N1, which is distributed on the pads of source 142, 144. Element 350 also covers element 120 at the level of node N2, which is distributed on the surface of component 120. This coverage as well as the possible associated welds or solders form the electric contact between the source 142, 144 of transistor 102 and second node N2, which is connected to the gate of transistor 102.

In an example, element 350 is a portion of a conduction node, for example a drain 340, of a transistor of the second die. This enables to limit as much as possible connection lengths.

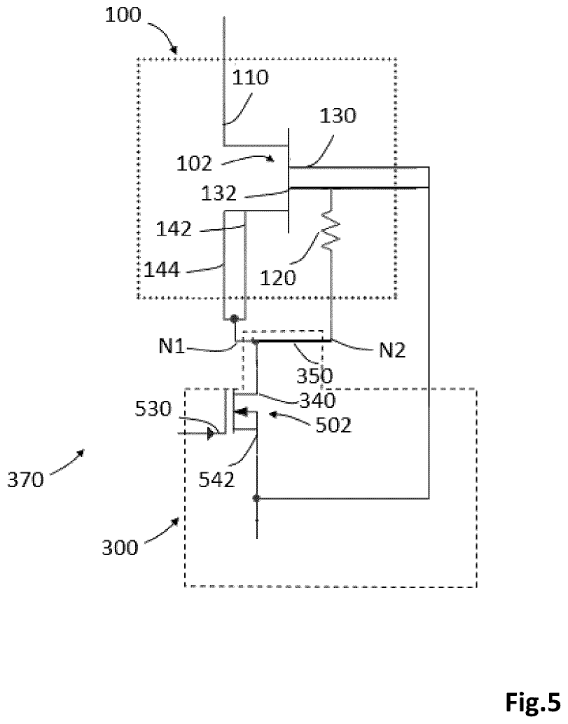

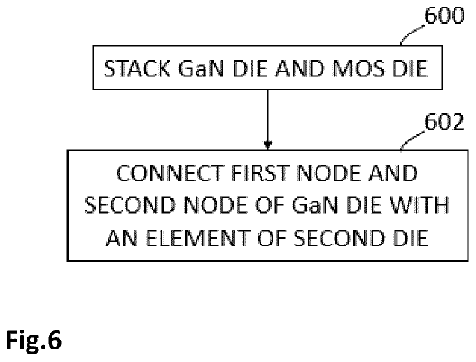

FIG. 5 schematically illustrates the electronic circuit of FIG. 3 according to an embodiment.

In the shown example, first die 100 including a circuit similar to that of FIG. 1 and the element 350 of second die 300 is a portion of the drain 340 of a transistor 502 of second die 300. In an example, the transistor 502 of second die 300 is of MOS (Metal Oxide Semiconductor) type and substrate 402 is based on silicon.

In the shown example, the source 542 of transistor 502 is coupled, preferably connected, to the control node 130, 132 of GaN transistor 102 of first die 100. This connection is for example performed similarly to the connecting of the first and the second node N1, N2. In this example, the source 542 of transistor 502 is connected to the substrate of transistor 502. The drain 340 of transistor 502 is connected to element 350 and thus also to nodes N1 and N2. Transistor 502 further including a control node 530.

The example of FIG. 5 thus forms a cascode-type circuit with the source 142, 144 of GaN transistor 102 in series with the drain 340 of transistor 502, and the gate 130, 132 of transistor 102 connected to the source 542 of transistor 502.

FIG. 6 illustrates a method of manufacturing the electronic circuit of FIG. 3.

In a first step 600 (STACK GaN DIE AND MOS DIE), the first and the second dies 100, 300 are for example stacked to place element 350 in front of the pads of source 142, 144 as well as of the surface of electronic component 120. Nodes N1 and N2 are, at this stage, disconnected.

In a second step 602 (CONNECT FIRST NODE AND SECOND NODE OF GaN DIE WITH AN ELEMENT OF SECOND DIE), the nodes N1 and N2 of first die 100 are electrically connected by element 350 of the second die. The connecting is either direct or via a weld or a solder and/or via alloys and/or by the application of a thermal treatment and/or of a pressure.

Before step 600, nodes N1 and N2 being disconnected, it is possible to test for example the resistance of component 120 and/or a leakage current of the gate of GaN transistor 102.

Various embodiments and variants have been described. Those skilled in the art will understand that certain features of these various embodiments and variants can be combined, and other variants will occur to those skilled in the art. In particular, clement 350 is formed by a plurality of points or conductive surfaces, in some embodiments.

Finally, the practical implementation of the described embodiments and variants is within the abilities of those skilled in the art based on the functional indications given hereabove. In particular, in one embodiment, element 350 is a conductive track or also be materialized by a conduction or control node or also a control node of a rear gate of the transistor 502 of second die 300. In one embodiment, element 350 is further be materialized by a portion of an electronic component such as a node of a diode or of an inductance or of a capacitive element, for example.

In the described examples, second die 300 is stacked on first die 100. However, in one embodiment the first die 100 is stacked on the second die 300.

In one embodiment, the electronic circuit is implemented in an automobile application, or in other applications using power.

In one embodiment, an electronic circuit (370) includes a first die (100), having a GaN transistor (102), and a second die (300), stacked so that an element (350) of the second die (300) electrically connects a first node (N1) and a second nodes (N2) of the first die (100) respectively coupled to a conduction node (140,142) and to a control node (130,132) of the GaN transistor (102).

In one embodiment, a method of manufacturing an electronic circuit (370) stacking a first die (100), having a GaN transistor (102) and a second die (300), so that an element (350) of the second die (100) electrically connects a first node (N1) and a second node (N2) of the first die respectively coupled to a conduction node (142, 144) and to a control node (130, 132) of the GaN transistor (102).

In one embodiment, the element (350) of the second die (300) includes a conductive track arranged on a first surface of the second die (300).

In one embodiment, the second die (300) is a die based on silicon.

In one embodiment, second die (300) includes at least one transistor (502).

In one embodiment, transistor (502) of the second die (300) is of MOS type and the GaN transistor (102) of the first die (100) is of HEMT type.

In one embodiment, the transistor (502) of the second die (300) includes a first conduction node (340) connected to the first node (N1) of the first die (100) via said element (350); and a second conduction node (542) connected to the control node (130,132) of the transistor (102) of the first die (100) via another element.

In one embodiment, an electric contact between said element (350) of the second die and the first and second nodes (N1, N2) of the first die (100) is a weld or a solder.

In one embodiment, the second node (N2) of the first die is coupled to the control node of the GaN transistor (102) via an electronic component (120).

In one embodiment, the electronic component (120) is active or passive.

In one embodiment, the electronic component (120) is configured to allow the establishing of an automatic operating point of the GaN transistor (102).

In one embodiment, the electronic component (120) is a resistor.

In one embodiment, before the stacking of the first and of the second dies (100, 300), the first and second nodes (N1, N2) of the first die (100) are disconnected from each other.

In one embodiment, before the stacking of the first and of the second dies (100, 300), a test of the electronic component (350) is performed.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic circuit, comprising:
a first die including:
a GaN transistor having a control node and a conduction node;
a first node coupled to the conduction node; and
a second node coupled to the control node; and
a second die stacked with the first die and including an element electrically coupling the first node to the conduction node, and electrically coupling the second node to the control node.

2. The circuit according to claim 1, wherein the element of the second die includes a conductive track arranged on a first surface of the second die.

3. The circuit according to claim 1, wherein the second die is a die based on silicon.

4. The circuit according to claim 1, wherein the second die includes at least one transistor.

5. The circuit according to claim 4, wherein the transistor of the second die is of MOS type and the GaN transistor of the first die is of HEMT type.

6. The circuit according to claim 4, wherein the transistor of the second die includes:
a first conduction node connected to the first node of the first die via the element; and
a second conduction node connected to the control node of the transistor of the first die via a second element.

7. The circuit according to claim 1, wherein an electric contact between the element of the second die and the first and second nodes of the first die is a weld or a solder.

8. The circuit according to claim 1, wherein the second node of the first die is coupled to the control node of the GaN transistor via an electronic component.

9. The circuit according to claim 8, wherein the electronic component is active or passive.

10. The circuit according to claim 8, wherein the electronic component is configured to allow the establishing of an automatic operating point of the GaN transistor.

11. The circuit according to claim 8, wherein the electronic component is a resistor.

12. A method of manufacturing an electronic circuit, comprising:
stacking a first die and a second die, wherein the stacking includes:
electrically coupling, with an element of the second die, a first node of the first die to a conduction node of a GaN transistor of the first die; and
electrically coupling, with the element, a second node of the first die to a control node of the GaN transistor.

13. The method according to claim 12, wherein, before the stacking of the first and of the second dies, the first and second nodes of the first die are disconnected from each other.

14. The method of claim 13, wherein after the stacking, the second node of the first die is coupled to the control node of the GaN transistor via an electronic component.

15. The method according to claim 14, comprising performing a test of the electronic component prior to stacking the first die and the second die.

16. A device, comprising:
a first die including:
a first GaN transistor including a control node and a conduction node; and
a first surface;
a first conductive track coupled to the conduction node and exposed at the first surface; and
a second conductive track coupled to the control node and exposed at the first surface; and
a second die including:
a second surface mounted to the first surface of the first die; and
a third conductive track exposed at the second surface and electrically coupled to the first conductive track and the second conductive track.

17. The device of claim 16, wherein the second die includes a second transistor.

18. The device of claim 17, wherein the second transistor includes a conduction node electrically coupled to the third conductive track.

19. The device of claim 16, comprising an adhesive film positioned between the third conductive track and the first and second conductive tracks.

20. The device of claim 16, wherein the first die includes a fourth conductive track coupled to the conduction node, wherein the fourth conductive track is exposed at the first surface and electrically coupled to the third conductive track.
